(19) United States
(12) Patent Application Publication
(10) Pub. No.: US 2026/0011391 A1
(43) Pub. Date: Jan. 8, 2026

(54) OPERATION METHOD FOR STACKED MEMORY DEVICE AND STACKED MEMORY DEVICE

(71) Applicant: Powerchip Semiconductor Manufacturing Corporation, Hsinchu (TW)

(72) Inventors: Makoto Muneyasu, Osaka (JP); Maiko Inoue, Osaka (JP); Takanobu Suzuki, Osaka (JP)

(73) Assignee: Powerchip Semiconductor Manufacturing Corporation, Hsinchu (TW)

(21) Appl. No.: 18/764,178

(22) Filed: Jul. 4, 2024

(51) Int. Cl. G11C 29/46; G11C 29/12

(52) U.S. Cl. CPC G11C 29/46; G11C 29/1201; G11C 29/12015

(57) ABSTRACT

A stack memory device and its operation method are provided. The stack memory device includes a memory chip having memory units, a logic chip bonded to the memory chip and an external port module. The logic chip has an OTP circuit storing operation information of the memory units; a memory controller, a peripheral controller, shifters, and selectors. Each o shifter receives a command, data and address from the peripheral controller, and transfers the command, data and address to each memory unit with a shift amount with respect to a clock signal. The peripheral controller is in a standby status when the stacked memory device is in an operation status, or the peripheral controller performs a memory test or controls of the non-volatile memory circuit.

### BACKGROUND

### Technical Field

The invention relates to an operation method for a stacked memory device and a stacked memory device.

### Description of Related Art

FIG. 1 illustrates a stacked memory device of the existent configuration. In FIG. 1, the stacked memory device 100, in general, has a logic chip 110 and a memory chip 120 that is bonded to the logic chip face-to-face. The memory chip 120 may be a DRAM chip. The logic chip 110 is connected to the memory chip 120 through the hybrid bond (HB) 140. In addition, the memory chip 120 is provided with through silicon via (TSV) and re-distribution layer (RDL) 126 that may be coupled to the external port 130, enabling device control from external sources.

In addition, the memory chip 120 is usually designed to be coupled to various logic devices. For example, the memory chip 120 may be cut from a memory wafer with a specific size to match the size of the logic chip 110. Required capacity of the memory chip 120 for the logic chip 110 varies based on the specification of different logic chip 110. Therefore. The number of the memory units (or memory tiles) 122 coupled to the logic chip 110 is not always the same.

In general, the memory units 122 of the memory chips 120 may have a non-volatile memory 124 respectively, such as laser fuses or One-Time Programmable (OTP) ROM to store address information of the faulty cells, adjustment information for internal power levels and operation timing of the memory chip 120. Such non-volatile memories 124 occupies a considerable area in the memory chip 120.

After the memory chip 120 is stacked to bond to the logic chip 110, the memory chip 120 is basically controlled by the logic chip 110. Therefore, it's difficult to directly access each memory unit 122 from external terminals. Therefore, in this configuration, when memory chip 120 are bonded to the logic chip 110, it is difficult to control the OTP circuit in the memory units and to directly access the memory units for test.

Therefore, there are needs to provide a means to control the OTP circuit and directly access memory chip after being stacked with the logic chip, even if the number of memory units coupled to the logic chip is varied due to the different requirements of the logic chip.

### SUMMARY

In view of the aforementioned descriptions, according to one embodiment of the invention, a stack memory device is provided. The stack memory device comprises at least memory chip, a logic chip and an external port module. The memory chip has a plurality of memory units. The logic chip is bonded to the memory chip in a face-to-face manner. The external port module has a plurality of external ports and coupled to the memory chip. The logic chip further comprises: a non-volatile memory circuit, configured to store operation information of the plurality of memory tiles; a memory controller, coupled to the plurality of memory units and configured to control operations of memory chip; a peripheral controller, coupled to the memory controller, the non-volatile memory circuit, the plurality of memory units and the external port module; a plurality of shifters, coupled to the memory controller, the peripheral controller, the external port module, and plurality of memory units respectively, each of the plurality of shifters being configured to receive a memory command, memory data and memory address from the peripheral controller, and to transfer the memory command, the memory data and the memory address to each of the memory units respectively with a shift amount with respect to a clock signal; and a plurality of selectors, coupled to the memory controller, the peripheral controller, the plurality of shifters respectively, and plurality of memory units respectively. The peripheral controller is in a standby status when the stacked memory device is in an operation status, or the peripheral controller is configured to perform a memory test or control of the non-volatile memory circuit.

According to one embodiment, in the above stacked memory device, the stacked memory device is configured to perform a reset procedure after the stacked memory device is powered on. In a case that the stacked memory device in the operation status, the memory controller is configured to control the memory units of the memory chip.

According to one embodiment, in the above stacked memory device, in the reset procedure, the memory controller sends a reset command to the peripheral controller, the plurality of shifters and the plurality of memory units.

According to one embodiment, in the above stacked memory device, after the reset procedure is finished, the peripheral controller is configured to read the operation information stored in the non-volatile memory circuit, and to transfer the operation information to each of the plurality of memory units of the memory chip.

According to one embodiment, in the above stacked memory device, in a case that the stacked memory device enters a memory test mode, the peripheral controller is further configured to receive commands, data and addresses from an external source via the external port module, and transfer the commands, the data and the addresses to the plurality of shifters, the plurality of shifters is configured to transfer the commands, the data and the addresses to the memory units of the memory chip, and after the plurality of memory units of the memory chip perform operations based on the commands, the data and the addresses, the plurality of memory units transfer results of the operations to the peripheral controller through the plurality of shifters.

According to one embodiment, in the above stacked memory device, in a case that the stacked memory device enters a non-volatile memory operation mode, the peripheral controller is further configured to send commands to the non-volatile memory circuit to control operations of the non-volatile memory circuit.

According to one embodiment, in the above stacked memory device, in a case that a memory direct test mode is entered, the plurality of memory units is configured to receive commands, data and addresses from an external source via the external port module without using the peripheral controller to detect failure bit addresses of each of the plurality of memory units.

According to one embodiment, in the above stacked memory device, the failure bit addresses is further written to the non-volatile memory circuit by the peripheral controller.

According to one embodiment, in the above stacked memory device, each of the plurality of selectors is a multiplexer.

According to one embodiment, in the above stacked memory device, the non-volatile memory circuit is a fuse memory circuit or a one-time programable (OTP) memory circuit and is configured to store information for the operations of the plurality of memory units of memory chip.

According to one embodiment, in the above stacked memory device, the logic chip is bonded to the memory chip with a hybrid bond, and the external port module is coupled to the memory chip with through silicon vias (TSVs) and re-distribution layers (RDLs).

According to one embodiment, in the above stacked memory device, the stacked memory device is a stacked DRAM device.

According to another embodiment of the invention, an operation method for a stacked memory device is provided. The stacked memory device including a memory chip with a plurality of memory units, a logic chip, bonded to the memory chip in a face-to-face manner, and an external port module coupled to the memory chip, the logic chip further including a non-volatile memory circuit that stores operation information of the plurality of memory units, a memory controller, a peripheral controller, a plurality of shifters, a plurality of selectors. The operation method comprises: performing a reset procedure after the stacked memory device is powered on; controlling the memory units of the memory chip by the memory controller and making the peripheral controller is in a standby status in a case that the stacked memory device is in the operation status; performing a memory test by the peripheral controller in a case that the stacked memory device is in a memory test mode; and controlling the non-volatile memory circuit by the peripheral controller in a case that the stacked memory device is in a non-volatile memory operation mode. In the memory test mode, the operation method further comprises: receiving a memory command, memory data and memory address by the peripheral controller from an external source through the external port module; transferring the memory command, the memory data and the memory address by the plurality of shifters to each of the memory units respectively with a shift amount with respect to a clock signal.

According to one embodiment, in the above operation method, in the reset procedure, the memory controller sends a reset command to the peripheral controller, the plurality of shifters and the plurality of memory units.

According to one embodiment, in the above operation method, after the reset procedure is finished, the peripheral controller is configured to read the operation information stored in the non-volatile memory circuit, and to transfer the operation information to each of the plurality of memory units of the memory chip.

According to one embodiment, in the above operation method, in a case that the stacked memory device enters the memory test mode, after the plurality of memory units of the memory chip perform operations based on the memory command, the memory data and the memory address, the plurality of memory units transfer results of the operations to the peripheral controller through the plurality of shifters.

According to one embodiment, in the above operation method, in a case that the stacked memory device enters the non-volatile memory operation mode, the peripheral controller is further configured to send commands to the non-volatile memory circuit to control operations of the non-volatile memory circuit.

According to one embodiment, in the above operation method, in a case that a memory direct test mode is entered, the plurality of memory units is configured to directly receive the memory command, the memory data and the memory address from the external source via the external port module without using the peripheral controller to detect failure bit addresses of each of the plurality of memory units.

According to one embodiment, in the above operation method, the failure bit addresses is further written to the non-volatile memory circuit by the peripheral controller.

According to one embodiment, in the above operation method, the stacked memory device is a stacked DRAM device.

According to the invention, in addition to the memory controller, the logic chip is further provided with the OTP circuit, the peripheral controller, the shifters, etc. Therefore, even though the memory chip is bonded to the logic chip, the peripheral controller may still receive signals from the external source, and thus the memory chip can be tested after being bonded to the logic chip. In addition, the OTP circuit is provided in the logic chip, so that the size of the memory chip can be further reduced. Furthermore, in such configuration, even though the memory chip is bonded to the logic chip, the OTP circuit can be still controlled by the peripheral controller.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a stacked memory device of the existent configuration.

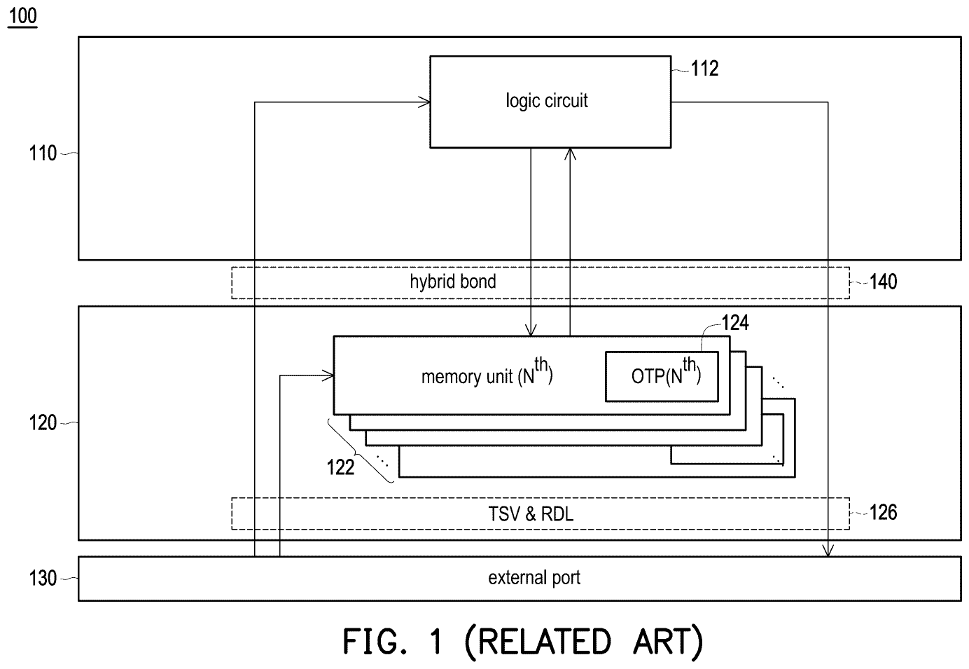

FIG. 2 illustrates a stacked memory device and a configuration for a logic device of the stacked memory device according to one embodiment of the invention.

FIG. 3 illustrates an exemplary configuration of the memory chip.

FIGS. 4A-4C illustrates operation modes that the stacked memory device can be performed according to the embodiment of the invention.

FIG. 5 illustrates command/signal/data transmission paths for the modes shown in FIGS. 4A-4C.

FIG. 6 illustrates reset procedure according to the embodiment of the invention.

FIG. 7 illustrates a timing chart for explaining the operation of the shifter.

### DESCRIPTION OF THE EMBODIMENTS

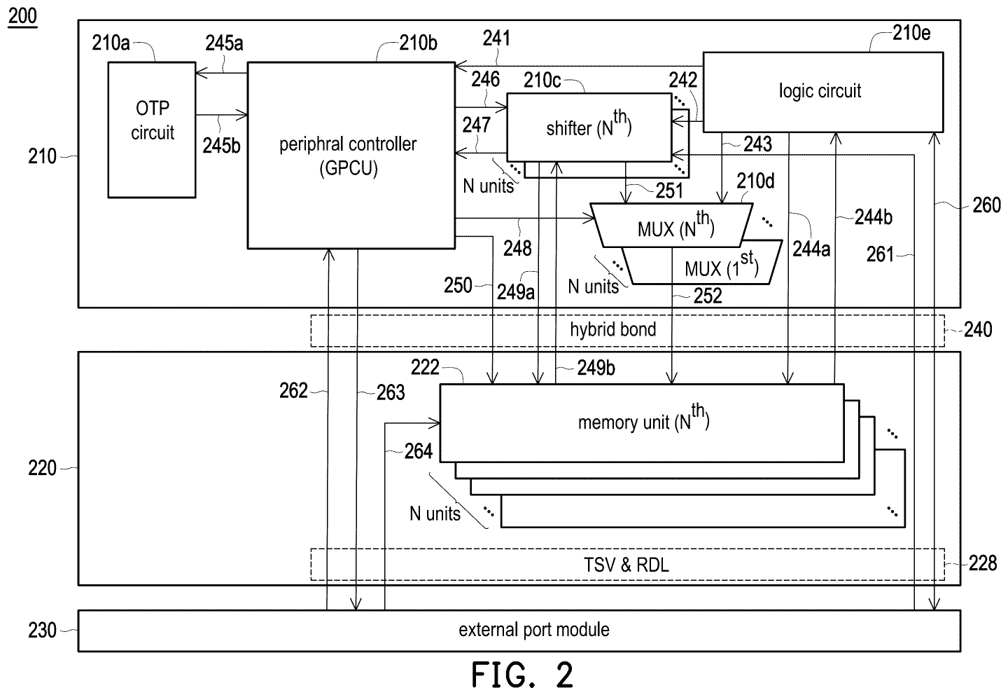

FIG. 2 illustrates a stacked memory device and a configuration for a logic device of the stacked memory device according to one embodiment of the invention. The stacked memory device 200 comprises a logic chip 210 and a memory chip 220. For the stacked memory device 200, the logic chip 210 is face-to-face bounded to the memory chip 220 through the hybrid bond 240. In an example, the memory chip 220 may be a DRAM chip, and the size of the logic chip 210 is basically the same as the memory chip 220. In addition, an external port module 230 may be further provided to be coupled to the memory chip 220 through connection structures 228 that include TSV and RDL.

In the embodiment, for simplification, the memory chip 220 comprises a plurality of memory units (or memory tiles) 222, such as having N DRAM tiles. The number (1˜N) of the plural shifters 210c and the number (1˜N) of the plural selectors are the same, and also respectively the same as the number (1˜N) of the memory units 222. The selectors may be multiplexers, for example, and the following descriptions multiplexers 210d will be used as examples.

According to the embodiment, the logic chip 210 may comprises at least a non-volatile memory circuit, a peripheral controller, a plurality of shifters 210c, a plurality of multiplexers 210d and a memory controller (such as a logic circuit 210e with DRAM controller), and functions and operations of these components will be described in detail below. In the embodiment, the non-volatile memory circuit is used to store operation information required for operations of the memory units 222 of the memory chip 220. In some examples, the non-volatile memory circuit may be implemented by an OTP circuit or a fuse circuit, and an OTP circuit is 210a used as an example for the following descriptions.

The peripheral controller is used to control the peripheral components, such as the OTP circuit 210a, the shifters 210c and the multiplexers 210d, and may be referred to a general peripheral control unit (GPCU), which the GPCU 210b is used as an example, hereinafter. The GPCU 210b is configured to control the memory units 222, the OTP circuit 210a, the shifters 210c, and the multiplexers (MUX) 210d in functions, such as OTP information load, OTP operation, and GPCU memory test.

The GPCU 210b may be also configured to communicate with external source (such as a testing machine) through the external port module 230. In addition, the GPCU 210b may be also configured to communicate with the memory units 222 of the memory chip 220.

The shifters 210c are configured to transfer commands (control signals) from the GPCU 210b to the memory units 222. These N shifters 210c are serially connected, and each shifter 210c is connected to a corresponding memory unit 222 through a corresponding multiplexer 210d. This configuration allows for a reduction in the number of signals compared to individually controlling the memory units 222 from the GPCU 210b. In operation, when each shifter 210c receive a signal (such as command, address, data, etc.) from the GPCU 210b, the shifter 210c is configured to shift the received signal with a predetermined period with respect to a clock signal.

The multiplexers 210d may deliver the signals, such as command, address data to the memory units 222. The multiplexers 210d may select signals from the logic circuit 210e or the signals from the shifters 210c.

The logic circuit 210e is coupled to and control the GPCU 210b, the plurality of shifters 210c and the plurality of multiplexers 210d respectively through paths 241, 242, 243. In addition, the logic circuit 210e is further coupled to the memory units 222 through the paths 244a, 244b, through which the logic circuit 210e may control the memory units 222, and the memory units 222 may provide the operation result based on the received command to the logic circuit 210e.

The GPCU 210b and the OTP circuit 210a are coupled to each other through paths 245a, 245b, so that the GPCU 210b may send a command (OTP command) to the OTP circuit 210a, and the OTP circuit 210a may transmit the OTP information to the GPCU 210b, or perform operation based on the command and then provide a result of the operation to the GPCU 210b.

The GPCU 210b is further connected to the shifters 210c through path 246, 247, and connected to the multiplexers 210d through path 248. In this way, when performing the GPCU memory test, the GPCU 210b may transfer the signals to the shifters 210c, and then to the memory units 222 through the multiplexers 210d. In this case, the shifters 210c may also transmit the signals to the memory units 222 through path 249a, and then the memory units 222 may provide operation result to the shifters 210c through path 249b.

In addition, the GPCU 210b may receive signals from or transmit signals to the external source via the external port module 230 through paths 262, 263. The memory units 222 may receive signals from the external source via the external port module 230 through path 264. In addition, the logic circuit 210e may communicate with the external source via the external port module 230 through path 260. The shifters 210c may receive signals from the external source via the external port module 230 through path 261.

In this simplified diagram of FIG. 2, the signals between each component are indicated by arrows. However, the aforementioned circuit configuration is an example, and other arrangement may be adopted and the invention does not particularly limit the circuit design.

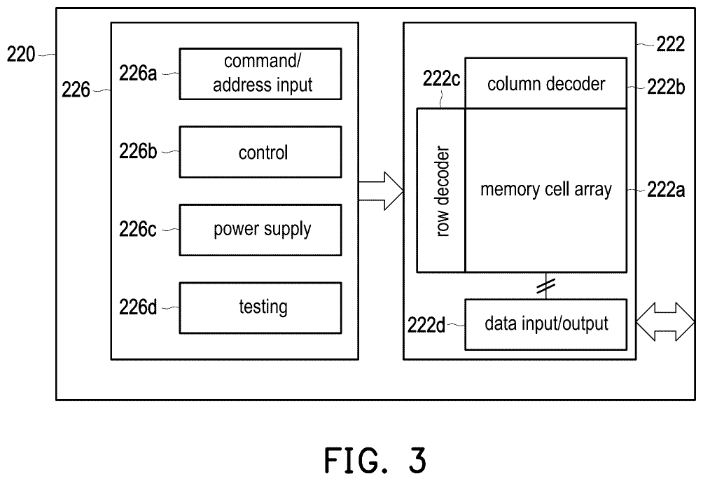

FIG. 3 illustrates an exemplary configuration of the memory chip 220. The memory chip 220 for example comprises a memory module 222 and a peripheral module 226. The memory module 222 may further comprises memory cell array 222a, functions or blocks for column decoder 222b, row decoder 222c, data input/out 222d. The peripheral module 226 may further comprises at least functions or blocks, such as command/address input functions or blocks 226a, control functions or blocks 226b, power supply functions or blocks 226c, and testing functions or blocks 226d. According to the embodiment of the invention, some of circuits for these functions of the periphery module 226 are transferred to the logic chip 210. This configuration enhances the cell occupancy rate of DRAM, thereby improving the area efficiency of memory chip 220. For example, the non-volatile memory (OTP) circuit 210a may be provided in the logic chip 210, rather than the memory chip 220.

The OTP information will be further described as follows. In general, the memory chip 220 is usually provided with redundant cells. The redundant cells may be used to replace the faulty cells. However, to perform the replacement, the address information of the faulty cell is required. In addition, information is further required to adjust the internal power levels and operation timing of memory chip 220. The OTP circuit 210a, which is an example of the non-volatile memory, is configure to store the information required for the memory units 222 of the memory chip 220. The information may include failure bit address of the memory array of the memory units 222, or the internal voltage setting of the memory power generator, or timing setting of the memory circuits. In the embodiment, the non-volatile memory circuit such as laser fuses or One-Time Programmable (OTP) ROM to store these information (i.e., operation information for memory) is provided in the logic chip 210.

Furthermore, the OTP circuit 210a also includes functions (OTP operation) to transmit the operation information from the OTP circuit 210a to the memory units 222 (i.e., the OTP information load) and to write the information to OTP circuit 210a. In addition, according to the logic chip 210 of the embodiment, for example, the OTP circuit 210a is provided in the logic chip 210 and this configuration allows an enhancement of the cell occupancy rate even when reducing the unit capacity of memory units 222.

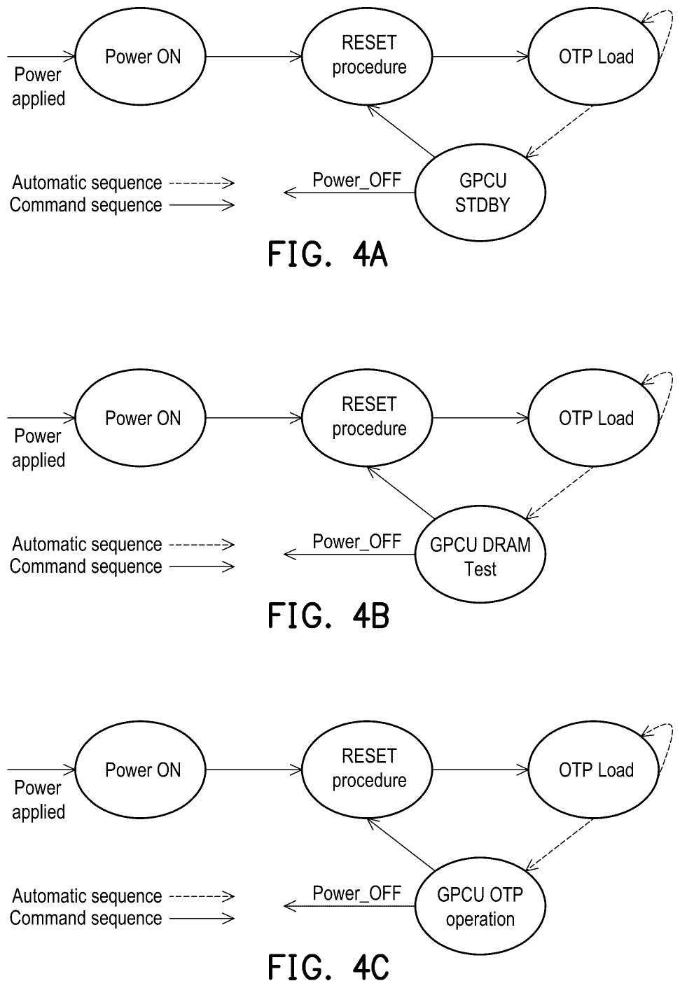

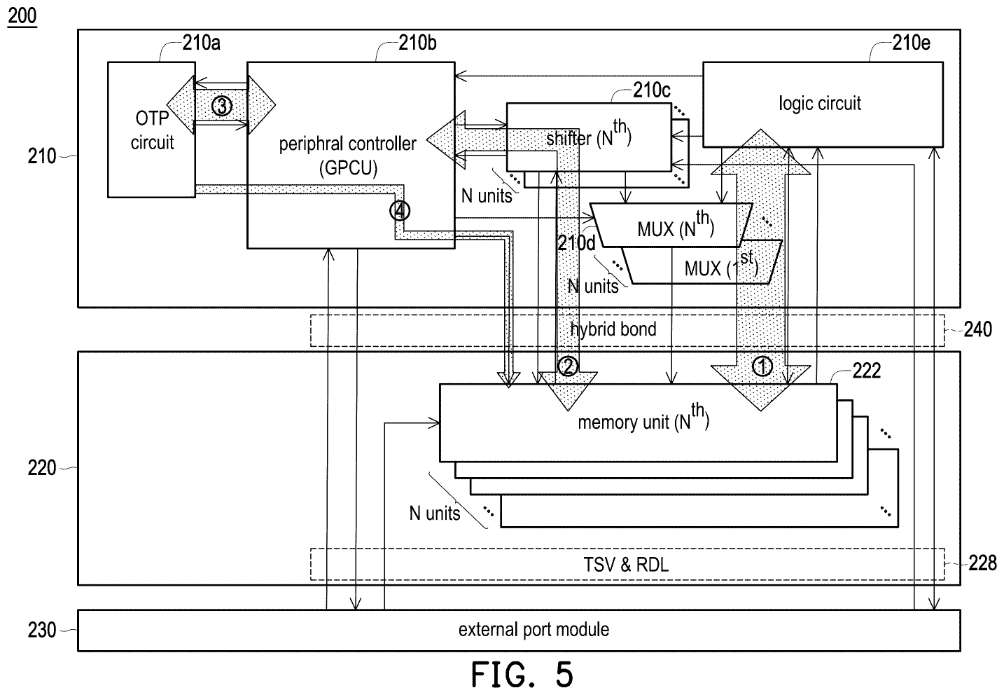

The operations or control method of the stacked memory, especially, the logic chip 210, may comprise operations of reset, OTP data load, memory access, DRAM direct testing, GPCU OTP operation, and GPCU DRAM test operation. Followings will describe these operations in details. FIGS. 4A-4C illustrates operation modes that the stacked memory device can be performed according to the embodiment of the invention. FIG. 5 illustrates command signal/data transmission paths for the modes shown in FIGS. 4A-4C. In FIGS. 4A-4C, the operation modes comprise at least a user mode (normal mode), a first test mode (GPCU DRAM test mode) and a second test mode (GPCU OTP operation mode). In addition, In FIGS. 4A-4C, the solid lines mean a command sequence, and the dashed line means an automatic sequence.

In FIG. 4A, regarding the user mode (normal mode, normal operation of the stacked memory device during ordinary operation, or operation status), first, after the stacked memory device 200 is powered on, a RESET procedure is performed. For example, the logic circuit 210e send a reset command to the GPUC 210b, the plurality of shifters 210c and the plurality of memory units 222 (paths 241, 242, 244a in FIG. 2). Then, after the RESET procedure is finished, an information load procedure is performed (the path (4) in FIG. 5). The GPCU 210b send command to the OTP circuit 210a, and the OTP circuit 210a provide the OTP information to the GPCU 210b, and then to the memory units 222. Namely, after the reset is released, the OTP information is loaded automatically. At the beginning, when the clock CLK is supplied from the logic circuit 210e to the GPCU 210b, the GPCU 210b initiates the control of the OTP circuit 210a. In accordance with the control of the GPCU 210b, a read operation on the OTP circuit 210a is performed and the OTP information stored in the OTP circuit 210a is transmitted to the GPCU circuit (path 245b). Then, the GPCU 210b sequentially outputs the received OTP information to the plurality of memory units 222 (path 250 in FIG. 2). Then, each of the plurality of the memory units 222 receives the OTP information from the GPCU 210b, and the loading of the OTP information load is completed.

When all of the plurality of memory units 222 receive the OTP information, the path (1) in FIG. 5 is established between the logic circuit 210e and the memory units 222, so that the memory chip 220 can be controlled by the logic circuit 210e. As a result, after the OTP information is sent to the memory units 222, the GPCU 210b is automatically in the standby mode until the power is turn off.

In the user mode, after the OTP information is loaded to the memory units 222, the memory units (such as DRAM) 222 may be accessed from the logic circuit 210e. When the clock is supplied from the logic circuit 210e to memory units 222 (path 244a in FIG. 2), the logic circuit 210e outputs the commands and addresses to the memory units 222 through multiplexers 210d (paths 243, 252 in FIG. 2). Then, the memory units 222 of the memory chip 220 may execute the operation based on the received command (such as read, write, refresh, etc.) and address. For example, during a read operation, the memory units 222 may output the stored data to logic circuit 210e (path 244b).

In FIG. 4B, regarding the first test mode (GPCU memory test mode), first, after the stacked memory device 200 is powered on, a RESET procedure is performed. For example, the logic circuit 210e send a reset command to the GPUC 210b, the plurality of shifters 210c and the plurality of memory units 222 (path 241, 242, 244a in FIG. 2). Then, after the RESET procedure is finished, an information load procedure is performed. The GPCU 210b send command to the OTP circuit 210a, and the OTP circuit 210a provide the OTP information to the GPCU 210b, and then to the memory units 222 (the path 4) in FIG. 5). The reset procedure and the loading of the OTP information are the same as the normal mode, and thus their descriptions are omitted, which can refer to the descriptions related to FIG. 4A.

After the OTP information is loaded to each of the memory units 222, the GPCU memory test is automatically performed. A bi-direction transmission between the GPCU 210b and the memory units 222 for testing can be performed through the plurality of shifters 210c (the path (2) in FIG. 5).

In the GPCU memory test mode, the clock signal and the mode signal (test mode) are supplied from the external port module 230 to the logic circuit 210e, the GPCU 210b, the plurality of shifters 210c, and the memory units 222 (paths 260, 261, 262, 264 in FIG. 2). In addition, the mode signal from the GPCU 210b is further supplied to the plurality of multiplexers 210d (path 248 in FIG. 2). This configuration enables a path to control the memory units 222 of the memory chip 220 from the external port module 230 through the GPCU 210b, the plurality of shifters 210c, and the plurality of multiplexers 210d.

Each of the plurality of shifters 210c may comprises one or more registers (not shown) to store addresses, data, and commands. The N shifters 210c are serially connected to form a shift register with these registers.

When performing the memory test, the addresses and data of the first to the N-th memory units 222 are sequentially input to the GPCU 210b from the external port module 230, and then the command are also inputted (path 262 in FIG. 2). After the GPCU 210b receives the addresses and data, and the addresses and data for the first to the N-th memory units 222 are outputted to the first shifter 210c (path 246 in FIG. 2). Then, the addresses and data are serially transferred to the registers of all N shifters 210c.

Then, similarly, after the GPCU 210b receives the command, the received command is then output from the GPCU 210b to the first shifter 210c (path 246 in FIG. 2), and then is serially transferred to the registers of all N shifters 210c. When the command is transferred to each shifter 210c, each of the shifters 210c outputs the command, address, and data to the memory units 222 through the multiplexers 210d (path 251, 252 in FIG. 2) or directly (path 249a in FIG. 2). This allows the memory units 222 to operate, so that the memory test (DRAM test) is executed.

The output data from the memory units 222 is asynchronously output to the external port module 230 through the shifters 210c and the GPCU 210b for Pass/Fail judgment of the memory test (paths 249b, 247, 263 in FIG. 2). In addition, in the embodiment of the invention, the memory test from the GPCU 210b may supports all commands (including test mode), i.e., all DRAM commands in this example. In addition, during the memory test, any one or more memory units 222 of the memory chip 220 may be freely selected without particular limitation.

In FIG. 4C, regarding the second test mode (GPCU OTP operation mode), first, after the stacked memory device 200 is powered on, a RESET procedure is performed. For example, the logic circuit 210e send a reset command to the GPUC 210b, the plurality of shifters 210c and the plurality of memory units 222 (path 241, 242, 244a in FIG. 2). Then, after the RESET procedure is finished, an information load procedure is performed. The GPCU 210b send command to the OTP circuit 210a, and the OTP circuit 210a provide the OTP information to the GPCU 210b, and then to the memory units 222 (the path (4) in FIG. 5). The reset procedure and the loading of the OTP information are the same as the normal mode, and thus their descriptions are omitted, which can refer to the descriptions related to FIG. 4A.

After the OTP information is loaded to each of the memory units 222, the GPCU OTP mode is automatically performed (path (3) FIG. 5). In the GPCU OTP operation, the clock signal and the mode signal, data signal are supplied from the external port module 230 to the logic circuit 210e, the GPCU 210b, the plurality of shifters 210c, and the plurality of memory units 222 (paths 260, 261, 262, 264 in FIG. 2). This configuration enables a path to control the OTP circuit 210a from the external port module 230 through the GPCU 210b.

In addition, the GPCU 210b may be provided with a GPCU OTP test circuit (not shown), and the GPCU OTP test circuit may have command decode for such as OTP testing, guard key unit, OTP mode enable signal register, OTP data latches, OTP address generation unit, and a verify unit. According to the commands, GPCU 210b may execute reset, enter/exit GPCU memory test mode, OTP standby, set OTP program mode/read mode, OTP enable, set OTP address, set OTP data, and perform program/read (path 245a in FIG. 2). For example, the guard key is a protection function to prevent accidental access to the OTP circuit 210a. Regarding the reading, the parallel data may be read from the OTP circuit 210a and is converted to serial data and output to the logic circuit 210e. Regarding the verification, the OTP circuit 210a may output a comparison result (for example, 1 bit) between the read data and a target value, so as to determine whether the OTP information is correct or not.

Therefore, according to the embodiment of the invention, by the GPCU 210b and OTP circuit 210a, the OTP circuit 210a may be controlled by the GPCU 210b according to the command and/or data from the external port module 230. Therefore, under such configuration of the logic chip 210 and memory chip 220, even though the logic chip 210 is bonded to the memory chip 220, the OTP circuit 210a may be still controlled.

In addition, according to the embodiment of the invention, the memory units 222 of the memory chip 220 may be directly tested through the external port module 230 (path 264 in FIG. 2) without using the GPCU 210b. Failure bit addresses may be detected and collected by this memory direct test, and this information may be further programmed to the OTP circuit 210a by the GPCU 210b. The external ports of the external port module 230 used in this testing may be probe pads, and these ports may become unavailable after packaging the stacked memory device 200.

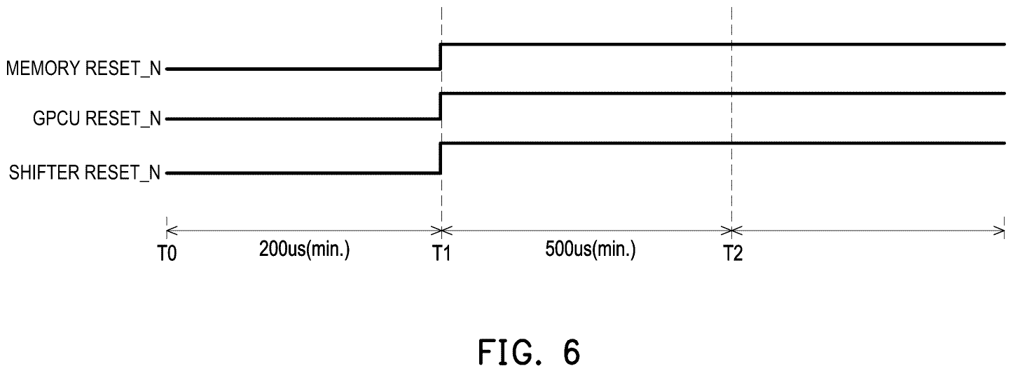

FIG. 6 illustrates reset procedure according to the embodiment of the invention. As described above, when entering the user mode, the GPCU memory test mode or OTP operation mode, the rest procedure is first performed after the power of the stacked memory device is turned on. When the rest procedure is performed, the logic circuit (or memory controller) 210e sends a reset command RESET_N to the GPCU 210b, the shifters 210c and the memory units 222 of the memory chip 220 at time TO.

At the beginning, the reset command RESET_N is at the low level. Then, the level of the reset command RESET_N goes high at time T1. During the period T0 to T1, the GPCU 210b, the shifters 210c and the memory units 222 are reset, and the logic circuit (or memory controller) 210e is not available to access the memory units 222 during the period T0 to T1.

In addition, during the period T1 to T2, the reset command RESET_N is at the high level. In this period T1 to T2, the GPCU 210b perform OTP load operation, and the OTP information (operation information) is read by the GPCU 210b and transferred to the memory units 222. In this period, the logic circuit (or memory controller) 210e is not available to access the memory units 222. At this time, the memory units 222 get the OTP information from the GPCU 210b, and the internal state of the memory units 222 is initialized. In addition, the shifters 210c are no operation in this period.

Then, during the period after T2, the logic circuit (or memory controller) 210e is available to access the memory units 222. The GPCU 210b and the shifters 210c are no operation (standby) in the normal mode.

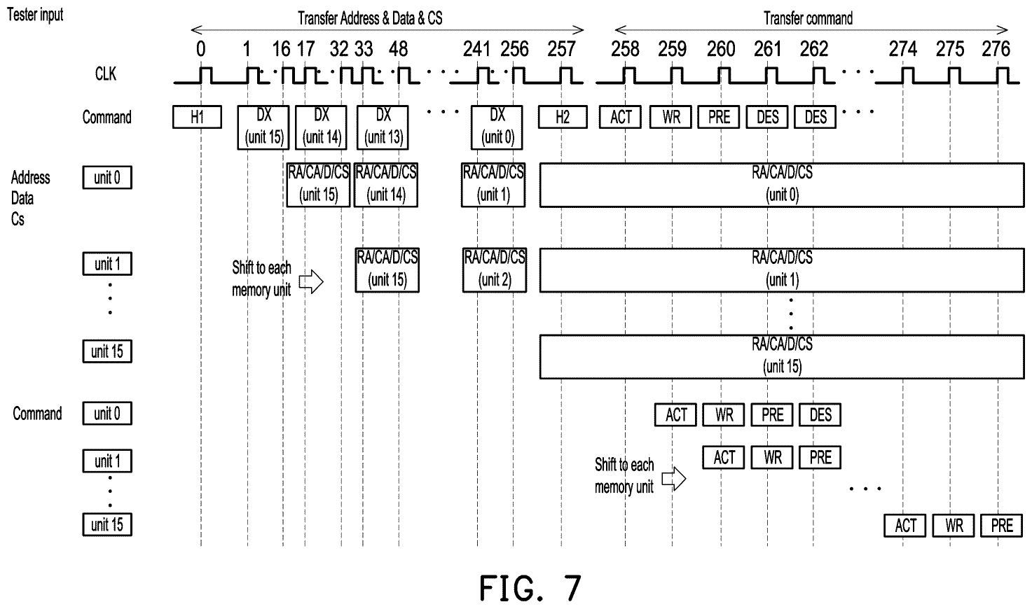

FIG. 7 illustrates a timing chart for explaining the operation of the shifter. The external source, such as a testing machine or tester, provides the commands to the GPCU 210b through the external port module 230. Then, the GPCU 210b further transmits the commands to the shifters 210c. The commands inputted by the external source comprises a header H1 that indicates the following data pack DX is to be transferred to the memory units 222 and a header H2 that indicates the following command is to control the memory units 222. The data pack DX includes address (RA/CA), data (D), chip select (CS), etc. The command may include active ACT, write WR, precharge PRE, device deselect DES, etc.

After the GPCU 210b receives these data pack DX and commands, these data pack DX and commands are further provided to the shifters 210c. Then, in the phase of transferring address (RA/CA), data (D) and chip select (CS), the address (RA/CA), data (D) and chip select (CS) for each memory unit 222 is respectively shifted with a period with respect to the clock signal CLK. Then, the commands for each memory unit 222 is respectively shifted with a period with respect to the clock signal CLK.

As shown in FIG. 7, once the commands ACT, WR, PRE, DES are sent to the unit0, the data D is started to be written to the specified address RA, CA. This shifting operation is continuously performed by the shifters 210c until all data and command for each memory unit 22 are transmitted completely.

According to the invention, in addition to the memory controller (logic circuit), the logic chip is further provided with the OTP circuit, the peripheral controller (GPCU), the shifters, etc. Therefore, even though the memory chip is bonded to the logic chip, the peripheral controller (GPCU) may still receive signals (command, data, etc.) from the external source (testing machine), and thus the memory chip can be tested after being bonded to the logic chip. In addition, the OTP circuit is provided in the logic chip, so that the size of the memory chip can be further reduced. Furthermore, in such configuration, even though the memory chip is bonded to the logic chip, the OTP circuit can be still controlled by the peripheral controller (GPCU).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A stacked memory device, comprising:
a memory chip, having a plurality of memory units;
a logic chip, bonded to the memory chip in a face-to-face manner; and
an external port module, having a plurality of external ports and coupled to the memory chip, wherein the logic chip further comprises:
a non-volatile memory circuit, configured to store operation information of the plurality of memory units;
a memory controller, coupled to the plurality of memory units and configured to control operations of memory chip;
a peripheral controller, coupled to the memory controller, the non-volatile memory circuit, the plurality of memory units and the external port module,
a plurality of shifters, coupled to the memory controller, the peripheral controller, the external port module, and plurality of memory units respectively, each of the plurality of shifters being configured to receive a memory command, memory data and memory address from the peripheral controller, and to transfer the memory command, the memory data and the memory address to each of the memory units respectively with a shift amount with respect to a clock signal,
a plurality of selectors, coupled to the memory controller, the peripheral controller, the plurality of shifters respectively, and plurality of memory units respectively,
wherein the peripheral controller is in a standby status when the stacked memory device is in an operation status, or the peripheral controller is configured to perform a memory test or control of the non-volatile memory circuit.

2. The stacked memory device according to claim 1, wherein the stacked memory device is configured to perform a reset procedure after the stacked memory device is powered on, and
in a case that the stacked memory device in the operation status, the memory controller is configured to control the memory units of the memory chip.

3. The stacked memory device according to claim 1, wherein in the reset procedure, the memory controller sends a reset command to the peripheral controller, the plurality of shifters and the plurality of memory units.

4. The stacked memory device according to claim 3, wherein after the reset procedure is finished, the peripheral controller is configured to read the operation information stored in the non-volatile memory circuit, and to transfer the operation information to each of the plurality of memory units of the memory chip.

5. The stacked memory device according to claim 1, wherein in a case that the stacked memory device enters a memory test mode,
the peripheral controller is further configured to receive the memory command, the memory data and the memory address from an external source via the external port module, and transfer the memory command, the memory data and the memory address to the plurality of shifters,
the plurality of shifters is configured to transfer the memory command, the memory data and the memory address to the memory units of the memory chip, and
after the plurality of memory units of the memory chip perform operations based on the memory command, the memory data and the memory address, the plurality of memory units transfer results of the operations to the peripheral controller through the plurality of shifters.

6. The stacked memory device according to claim 1, wherein in a case that the stacked memory device enters a non-volatile memory operation mode,
the peripheral controller is further configured to send commands to the non-volatile memory circuit to control operations of the non-volatile memory circuit.

7. The stacked memory device according to claim 1, wherein in a case that a memory direct test mode is entered,
the plurality of memory units is configured to directly receive the memory command, the memory data and the memory address from an external source via the external port module without using the peripheral controller to detect failure bit addresses of each of the plurality of memory units.

8. The stacked memory device according to claim 7, wherein the failure bit addresses are further written to the non-volatile memory circuit by the peripheral controller.

9. The stacked memory device according to claim 1, wherein each of the plurality of selectors is a multiplexer.

10. The stacked memory device according to claim 1, wherein the non-volatile memory circuit is a fuse memory circuit or a one-time programmable (OTP) memory circuit and is configured to store information for the operations of the plurality of memory units of memory chip.

11. The stacked memory device according to claim 1, wherein the logic chip is bonded to the memory chip with a hybrid bond, and the external port module is coupled to the memory chip with through silicon vias (TSVs) and re-distribution layers (RDLs).

12. The stacked memory device according to claim 1, wherein the stacked memory device is a stacked DRAM device.

13. An operation method for a stacked memory device, the stacked memory device including a memory chip with a plurality of memory units, a logic chip, bonded to the memory chip in a face-to-face manner, and an external port module coupled to the memory chip, the logic chip further including a non-volatile memory circuit that stores operation information of the plurality of memory units, a memory controller, a peripheral controller, a plurality of shifters, a plurality of selectors, the operation method comprising:
performing a reset procedure after the stacked memory device is powered on;
controlling the memory units of the memory chip by the memory controller and making the peripheral controller is in a standby status in a case that the stacked memory device is in the operation status;
performing a memory test by the peripheral controller in a case that the stacked memory device is in a memory test mode; and
controlling the non-volatile memory circuit by the peripheral controller in a case that the stacked memory device is in a non-volatile memory operation mode,
wherein in the memory test mode, the plurality of memory units may be directly or indirectly tested through the external port module.

14. The operation method according to claim 13, wherein in the reset procedure, the memory controller sends a reset command to the peripheral controller, the plurality of shifters and the plurality of memory units.

15. The operation method according to claim 14, wherein after the reset procedure is finished, the peripheral controller is configured to read the operation information stored in the non-volatile memory circuit, and to transfer the operation information to each of the plurality of memory units of the memory chip.

16. The operation method according to claim 13, wherein in a case that the plurality of memory units is indirectly tested through the external port module, the operation method further comprises:
receiving a memory command, memory data and memory address by the peripheral controller from an external source through the external port module;
transferring the memory command, the memory data and the memory address by the plurality of shifters to each of the memory units respectively with a shift amount with respect to a clock signal; and,
transferring results of the operations to the peripheral controller through the plurality of shifters.

17. The operation method according to claim 13, wherein in a case that the stacked memory device enters the non-volatile memory operation mode,
the peripheral controller is further configured to send commands to the non-volatile memory circuit to control operations of the non-volatile memory circuit.

18. The operation method according to claim 13, wherein in a case that the plurality of memory units is directly tested through the external port module,
the plurality of memory units is configured to directly receive the memory command, the memory data and the memory address from the external source via the external port module without using the peripheral controller to detect failure bit addresses of each of the plurality of memory units.

19. The operation method according to claim 18, wherein the failure bit addresses are further written to the non-volatile memory circuit by the peripheral controller.

20. The operation method according to claim 18, wherein the stacked memory device is a stacked DRAM device.
